(19) United States
(12) Patent Application Publication
(10) Pub. No.: US 2010/0109045 A1
(43) Pub. Date: May 6, 2010

(54) INTEGRATED CIRCUIT SYSTEM EMPLOYING STRESS-ENGINEERED LAYERS

(75) Inventors: Jin Ping Liu, Singapore (SG); Yisuo Li, Singapore (SG); Alex K.H. See, Singapore (SG); Meisheng Zhou, Singapore (SG); Liang-Choo Hsia, Singapore (SG)

Correspondence Address: LAW OFFICES OF MIKIO ISHIMARU, 333 W. EL CAMINO REAL, SUITE 330, SUNNYVALE, CA, 94087, US

(73) Assignee: CHARTERED SEMICONDUCTOR MANUFACTURING LTD., Singapore (SG)

(21) Appl. No.: 12/262,128

(22) Filed: Oct. 30, 2008

(51) Int. Cl. H01L 21/20; H01L 29/06

(52) U.S. Cl. 257/190; 438/478; 257/E21.09; 257/E29.005

(57) ABSTRACT

An integrated circuit system that includes: providing a substrate including an active device; forming a trench within the substrate adjacent the active device; forming a first layer with a first lattice constant within the trench; and forming a second layer with a second lattice constant over the first layer, the second lattice constant differing from the first lattice constant.

### TECHNICAL FIELD

The present invention relates generally to integrated circuits, and more particularly to an integrated circuit system employing stress-engineered layers.

### BACKGROUND ART

Integrated circuits are used in many portable electronic products, such as cell phones, portable computers, voice recorders, etc., as well as in many larger electronic systems, such as cars, planes, industrial control systems, etc. Integrated circuits may include a combination of active devices, passive devices and their interconnections.

Active devices, such as a metal-oxide-semiconductor field-effect transistor (MOSFET), generally include a semiconductor substrate, having a source, a drain, and a channel located between the source and drain. A gate stack composed of a conductive material (i.e.—a gate) and an oxide layer (i.e.—a gate oxide) are typically located directly above the channel. During operation, an inversion layer forms a conducting bridge or “channel” between the source and drain when a voltage is applied to the gate. Both p-channel and n-channel MOSFET technologies are available and can be combined on a single substrate in one technology, called complementary-metal-oxide-semiconductor or CMOS.

Scaling of the MOSFET, whether by itself or in a CMOS configuration, has become a major challenge for the semiconductor industry. Size reduction of the integral parts of a MOSFET has lead to improvements in device operation speed and packing density, but size reduction has its limits. For example, as scaling of the MOSFET reaches the submicron era, intended and unintended strain effects can become a design problem. Consequently, new methods must be developed to maintain the expected device performance enhancement from one generation of devices to the next.

Stress engineering has been a key element in the further scaling of both p-channel and n-channel MOSFET technologies. To date, more manufacturing solutions, such as improved SiGe epitaxy processes and improved compressive nitride processes, have been developed for p-channel MOSFET strain engineering techniques because it is believed that the theoretical limits of the saturated gain for a PMOS strained channel device can be four times (4×) over that of an unstrained channel device. Unfortunately, it has been more difficult for n-channel MOSFET technologies because there have been no successful alternatives to SiGe epitaxy and tensile nitride processes have not improved much even with UV-cure techniques. As such, it has been very difficult to achieve a saturated gain for an NMOS strained channel device that is two times (2×) that of an unstrained n-channel device.

Thus, a need still remains for a reliable integrated circuit system and method of fabrication, wherein the integrated circuit system exhibits improved carrier mobility due to the controlled application of stress to the channel of an active device. In view of the ever-increasing commercial competitive pressures, increasing consumer expectations, and diminishing opportunities for meaningful product differentiation in the marketplace, it is increasingly critical that answers be found to these problems. Moreover, the ever-increasing need to save costs, improve efficiencies, and meet such competitive pressures adds even greater urgency to the critical necessity that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a method for manufacturing an integrated circuit system including: providing a substrate including an active device; forming a trench within the substrate adjacent the active device; forming a first layer with a first lattice constant within the trench; and forming a second layer with a second lattice constant over the first layer, the second lattice constant differing from the first lattice constant.

Certain embodiments of the invention have other advantages in addition to or in place of those mentioned above. The advantages will become apparent to those skilled in the art from a reading of the following detailed description when taken with reference to the accompanying drawings.

### BRIEF DESCRIPTION OF THE DRAWINGS

FIG. 1 is a partial cross sectional view of an integrated circuit system in an initial stage of manufacture in accordance with an embodiment of the present invention;

FIG. 2 is the structure of FIG. 1 after the formation of a protective layer and a mask layer;

FIG. 3 is the structure of FIG. 2 after further processing;

FIG. 4 is the structure of FIG. 3 after formation of a first layer within a trench;

FIG. 5 is the structure of FIG. 4 after formation of a second layer within a trench;

FIG. 6 is the structure of FIG. 5 after further processing; and

FIG. 7 is a flow chart of an integrated circuit system for an integrated circuit system in accordance with an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the system are semi-diagrammatic and not to scale and, particularly, some of the dimensions are for the clarity of presentation and are shown exaggerated in the drawing FIGs. Additionally, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

The term “processing” as used herein includes deposition of material or photoresist, patterning, exposure, development, etching, cleaning, and/or removal of the material or photoresist as required in forming a described structure.

The term “on” is used herein to mean there is direct contact among elements.

The terms “example” or “exemplary” are used herein to mean serving as an instance or illustration. Any aspect or embodiment described herein as an “example” or as “exemplary” is not necessarily to be construed as preferred or advantageous over other aspects or designs.

The term “layer” encompasses both the singular and the plural unless otherwise indicated.

The terms “first” and “second” as used herein are for purposes of differentiation between elements only and are not to be construed as limiting the scope of the present invention.

The term “exhibiting the characteristics of stress memorization” as used herein includes a structure or element that has its physical properties affected by a stress memorization layer.

The term “active device” is used herein to mean a fully functioning and operable device that can increase the magnitude of a given electrical input parameter by merely establishing electrical contacts.

The term “system” as used herein means and refers to the method and to the apparatus of the present invention in accordance with the context in which the term is used.

Generally, the following embodiments relate to an active device, such as an NMOS device, with one or more lattice mismatched stressor materials formed adjacent a channel region. In one embodiment, the lattice mismatched stressor material may include a first material with a first lattice constant and a second material with a second lattice constant, wherein the first lattice constant is different from the second lattice constant. The method, system, and/or device of the present embodiments permits enhanced stress upon the channel region of an active device, thereby improving carrier mobility and the performance of the active device.

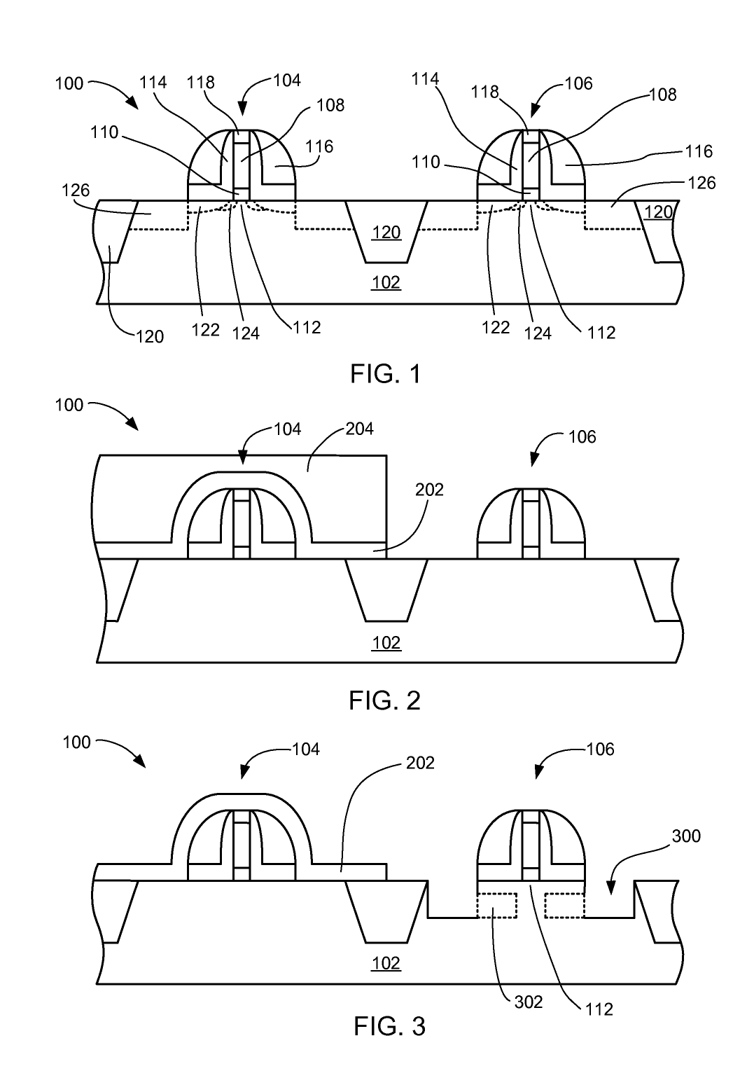

FIGS. 1-6, which follow, depict by way of example and not by limitation, an exemplary process for the formation of an integrated circuit system and they are not to be construed as limiting. It is to be understood that a plurality of conventional processes that are well known within the art and not repeated herein, may precede or follow FIGS. 1-6. Moreover, it is to be understood that many modifications, additions, and/or omissions may be made to the below described process without departing from the scope of the claimed subject matter. For example, the below described process may include more, fewer, or other steps. Additionally, steps may be performed in any suitable order without departing from the scope of the present invention.

Moreover, it is to be appreciated that the integrated circuit system of the present disclosure may include any number of multi-electrode devices (e.g., active device structures) in which the current flowing between two specified electrodes is controlled or modulated by the voltage applied at a control electrode. Exemplary illustrations may include a bipolar junction transistor (BJT), an n-channel metal-oxide semiconductor (NMOS), a p-channel metal-oxide semiconductor (PMOS), a complementary metal-oxide semiconductor (CMOS) configuration, a single-gate transistor, a multi-gate transistor, a fin-field effect transistor (fin-FET), or an annular gate transistor. Furthermore, it is to be understood that one or more of the integrated circuit system could be prepared at one time on a medium, which could be separated into individual or multiple integrated circuit assemblies at a later stage of fabrication.

Moreover, it will be appreciated by those skilled in the art that the techniques of the present embodiments can be used to fabricate an integrated circuit system, for example, an active device, using existing conventional NMOS, PMOS, and CMOS compatible process technology, thereby minimizing or reducing the cost of manufacturing.

Moreover, it is to be understood that the integrated circuit system manufactured by the embodiments described herein can be used within processor components, memory components, logic components, digital components, analog components, mixed-signal components, power components, radio-frequency (RF) components (e.g., RF CMOS circuits), digital signal processor components, micro-electromechanical components, optical sensor components, and so forth, in numerous configurations and arrangements as may be needed.

Referring now to FIG. 1, therein is shown a partial cross sectional view of an integrated circuit system 100 in an initial stage of manufacture in accordance with an embodiment of the present invention. In general, the integrated circuit system 100 may include one or more of an active device and/or a passive device. In such cases, a multitude of different regions (e.g., memory, logic, high voltage, etc.) can be formed over, on and/or within a substrate 102 for the manufacture of active and/or passive device structures by conventional deposition, patterning, photolithography, and etching techniques known in the semiconductor processing industry. Moreover, it will be appreciated by those skilled in the art that although the present embodiments are generally depicted with respect to a CMOS device structure, it is to be understood that the system and methods described herein are applicable to one or more NMOS active device structures formed within isolated, semi-dense or dense NMOS array configurations.

In some embodiments, the integrated circuit system 100 may include the substrate 102, such as a two hundred (200) mm or three hundred (300) mm semiconductor wafer, upon which any number of active and/or passive device structures and their interconnections could be formed. By way of example, the substrate 102 may include any semiconducting material, such as, Si, SiC, SiGe, Si/SiGe, SiGeC, Ge, GaAs, InAs, InP, other III/V or II/VI compound semiconductors, as well as silicon-on-insulator configurations. Additionally, the substrate 102 may also include doped and undoped configurations, epitaxial layers, strained configurations, and one or more crystal orientations (e.g.—<100>, <110>, and/or <111> orientations), which may be strategically employed to optimize carrier mobility within NMOS and PMOS devices. The substrate 102 may also include any material that becomes amorphous upon implantation.

In one embodiment, the substrate 102 may also include n-type wells where p-type MOSFETs may be formed, p-type wells where n-type MOSFETs may be formed, and/or twin well configurations. The active areas of the substrate 102 may also be implanted with a threshold voltage implant adjustment to optimize performance of any subsequently formed active devices.

In some embodiments, the substrate 102 may possess a thickness ranging from about one hundred (100) nanometers to about several hundred microns, for example.

However, the examples provided for the substrate 102 are not to be construed as limiting and the composition of the substrate 102 may include any surface, material, configuration, or thickness that physically and electrically enables the formation of active and/or passive device structures.

A first device 104 and a second device 106 can be formed over, on and/or within the substrate 102 by conventional deposition, patterning, photolithography, and etching techniques known in the semiconductor processing industry for the manufacture of active and/or passive devices. In some embodiments, the first device 104 and the second device 106 may include one or more of an active device, such as an NMOS device and a PMOS device. In other embodiments, the first device 104 and the second device 106 may include a PMOS device and an NMOS device cooperatively coupled, thereby forming a CMOS device. In a preferred embodiment, the first device 104 includes a PMOS device and the second device 106 includes an NMOS device. However, it is to be understood that the first device 104 and the second device 106 are not limited to the preceding examples and may include any number of multi-electrode devices in which the current flowing between two specified electrodes is controlled or modulated by the voltage applied at a control electrode.

In general, the first device 104 and the second device 106 both include a gate 108, a gate dielectric 110, a channel 112, a first spacer 114, a second spacer 116, a gate cap 118, and an isolation structure 120.

In some embodiments, the gate 108 may be formed from conventional materials including doped and undoped semiconducting materials (such as, for example, polySi, amorphous Si, or SiGe), a metal, a metallic alloy, a silicide, or a combination thereof, for example. In other embodiments, the gate 108 may also include any conducting material or composition that becomes amorphous upon implantation. The gate dielectric 110 may be made from materials including, but not limited to, silicon oxide, silicon oxynitride, silicon nitride, a silicon oxide/nitride/oxide stack, a high-k dielectric material (i.e., one having a dielectric constant value greater than silicon oxide), or a combination thereof. However, it is to be understood that the type of material chosen for the gate dielectric 110 is not limited to the preceding examples; for example, the gate dielectric 110 may include any material that permits induction of a charge in the channel 112 when an appropriate voltage is applied to the gate 108. Accordingly, other materials, which may be known to those skilled in the art for gate structures, may also be used for the gate 108 and the gate dielectric 110.

Generally, the thickness of the gate 108 is between about 500 angstroms and about 3000 angstroms and the thickness of the gate dielectric 110 is between about 10 angstroms and about 50 angstroms. However, larger or smaller thicknesses of the gate 108 and the gate dielectric 110 may be appropriate depending on the design specifications of the first device 104 and the second device 106.

The first spacer 114 may include dielectric materials such as an oxide, a nitride, or a combination thereof, but preferably includes silicon dioxide. The first spacer 114 can be formed by a variety of techniques, including, but not limited to, physical vapor deposition, chemical vapor deposition and thermal oxidation, followed by an appropriate anisotropic etch.

The second spacer 116 can be formed adjacent the first spacer 114 and typically includes a material (e.g., an oxide, a nitride, or a combination thereof) that can be selectively etched with respect to the material of the first spacer 114. For example, if the first spacer 114 is formed using silicon dioxide, the second spacer 116 can be formed using silicon nitride. For such a spacer material composition, a plurality of anisotropic etch recipes with moderately high etch selectivity are well know within the art. The second spacer 116 can be formed by a variety of techniques, including, but not limited to, chemical vapor deposition and physical vapor deposition, followed by an appropriate anisotropic etch.

In other embodiments, the first spacer 114 and/or the second spacer 116 may also include any type of stress-inducing material that transfers its inherent or intrinsic stress to the gate 108, the channel 112, a source/drain extension region, and/or a source/drain region. In such cases, the stress-inducing material may include a stress memorization material or a compressive and/or tensile stressed material. By way of example, when the first spacer 114 and/or the second spacer 116 include the characteristics of a stress memorization layer, the first spacer 114 and/or the second spacer 116 can transfer their intrinsic stress to an active device upon recrystallization of the amorphous regions within the active device. Generally, such techniques permit the first spacer 114 and/or the second spacer 116 to impart a compressive stress or a tensile stress upon the channel 112, thereby enhancing the amount of current that can flow through the device.

However, it is to be understood that the type of materials chosen for the first spacer 114 and the second spacer 116 are not limited to the above examples and may include any material that permits electrical isolation of the gate 108, formation of a lateral dopant profile within the substrate 102 adjacent the channel 112, and/or a moderately high etch selectivity between the first spacer 114 and the second spacer 116.

Moreover, it is to be understood that the thickness and/or width of each of the first spacer 114 and the second spacer 116 may determine, at least in part, the location of a subsequently formed source and drain region, a low resistance electrical contact, and/or the proximity of a subsequently deposited stressor layer to the channel 112. Accordingly, the thickness and/or width of each of the first spacer 114 and the second spacer 116 can be altered to meet the design specification (e.g., sub 45 nanometer technology node critical dimensions) of the integrated circuit system 100.

Generally, the first spacer 114 and/or the second spacer 116 may include a thickness ranging from about 20 angstroms to about 2000 angstroms. However, it is to be understood that the thickness of the first spacer 114 and/or the second spacer 116 may vary with the design specifications of the device. For example, the thickness of the first spacer 114 and/or the second spacer 116 may vary with the desired placement of a low resistance electrical contact over a source/drain region and its resultant proximity effects upon the channel 112 of an active device.

Furthermore, it will be appreciated by those skilled in the art that although the spacer structure is depicted as a combination of the first spacer 114 and the second spacer 116, it is to be understood that the spacer structure can be formed by one or more spacers.

The first device 104 and the second device 106 may also include the gate cap 118, such as a nitride or an oxynitride cap that can be formed over the gate 108, thereby helping to protect each of the gate 108 during subsequent processing steps.

The isolation structure 120, which may include a shallow trench isolation structure, a local oxidation of silicon structure, and/or other suitable isolation features, can electrically isolate and/or separate the first device 104 and the second device 106 from each other. In some embodiments, the isolation structure 120 can be made from a dielectric material such as silicon oxide, silicon nitride, or silicon oxynitride. In other embodiments, the isolation structure 120 may also include a multi-layer structure of one or more dielectric materials.

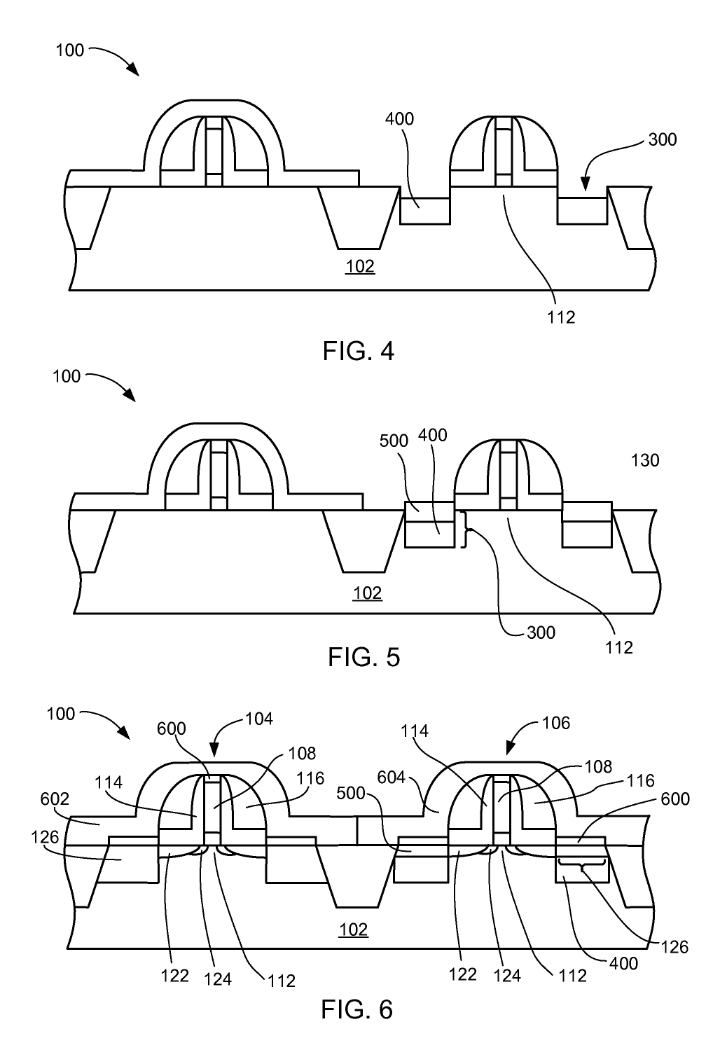

At this stage of manufacture, the integrated circuit system 100 may also include a source/drain extension 122, a halo 124, and/or a source/drain 126, shown in dashed outline as they are not required at this stage of manufacture. Accordingly, it will be appreciated by those skilled in the art that the source/drain extension 122, the halo 124, and/or the source/drain 126 can be formed at any stage during the fabrication process described herein. For example, the source/drain extension 122, the halo 124, and/or the source/drain 126 can be formed before or after forming a first layer 400, of FIG. 4, and a second layer 500, of FIG. 5. By way of another example, the first layer 400 and the second layer 500 can be formed after forming the source/drain extension 122 and the halo 124 but before forming the source/drain 126.

As is well known in the art, the source/drain extension 122 can be formed adjacent the channel 112. In general, the source/drain extension 122 may be formed to a shallow depth with a low concentration of impurities relative to a source and drain region to facilitate dimensional reductions for the scaling of the integrated circuit system 100. More specifically, the source/drain extension 122 can be formed from a dopant implant dose between about 1×10¹⁴ ions/cm² to about 5×10¹⁵ ions/cm². However, larger or smaller doses may be used depending upon the impurity used and the design specifications of the first device 104 and the second device 106. Moreover, it is to be understood that the above parameter is not limiting and those skilled in the art will appreciate that additional parameters may also be employed/manipulated to effectuate the purpose of implanting a highly-doped and abrupt form of the source/drain extension 122.

Generally, the source/drain extension 122 should be implanted with an energy that is insufficient to reach the first layer 400, thereby preventing implant damage or stress relaxation within the first layer 400. Accordingly, it will be appreciated by those skilled in the art that the implant energy used to form the source/drain extension 122 may vary with the thickness of the second layer 500. By way of example, the source/drain extension 122 can be implanted with an energy between approximately 100 eV and approximately 10 keV depending on the type of dopant used. As an exemplary illustration, arsenic may be implanted with an energy of about 2 keV for a 45 nm process, but will decrease further with shallower junction requirements.

However, it is to be understood that larger or smaller energies may be used depending on the impurity implanted and the design specifications of the active device. Moreover, it is to be understood that the above parameters are not limiting and those skilled in the art will appreciate that additional parameters may also be employed/manipulated to effectuate the purpose of implanting a highly confined form of the source/drain extension 122.

The impurities used to form the source/drain extension 122 may include n-type or p-type, depending on the first device 104 and/or the second device 106 being formed (e.g., n-type impurities for an NMOS device and p-type impurities for a PMOS device). It is to be understood that the source/drain extension 122 can be formed by aligning the source/drain extension 122 to the gate 108 (i.e., before forming the first spacer 114 and the second spacer 116) or subsequent to forming the first spacer 114 and the second spacer 116 by employing an angled implant.

As is known in the art, a halo implant can help to decrease the length of the channel 112, which may be advantageous for minimizing punchthrough current and controlling short channel effects, thereby improving the performance of an active device. In general, the halo 124 can be formed by implanting the substrate 102 with impurities of opposite conductivity type to that of the impurities used to form the source/drain 126 and the source/drain extension 122. For example, if the source/drain 126 and the source/drain extension 122 are formed with n-type impurities then the halo 124 can be formed with p-type impurities.

The halo dopant material is typically implanted at an angle so that the dopant material can be implanted underneath the first spacer 114, the second spacer 116, and the gate 108. In general, the angle of the implantation is typically substantially less than ninety degrees relative to the surface of the substrate 102, e.g., between about fifteen to about seventy-five degrees relative to the surface of the substrate 102. In some embodiments, the substrate 102 can be rotated (e.g., dual and quad halo implants) during the angled halo implantation to provide symmetrical forms of the halo 124. However, in other embodiments, the halo dopant implant may be implanted perpendicular to the surface of the substrate 102.

Generally, the halo 124 should be implanted with an energy that is insufficient to reach the first layer 400, thereby preventing implant damage or stress relaxation within the first layer 400. Accordingly, it will be appreciated by those skilled in the art that the implant energy used to form the halo 124 may vary with the thickness of the second layer 500. By way of example, the halo 124 can be implanted with an energy between approximately 5 keV and approximately 100 keV and a dose between about 1×10¹² ions/cm² and about 1×10¹⁴ ions/cm².

However, it is to be understood that larger or smaller energies and doses may be used depending on the impurity implanted and the design specifications of the active device. Moreover, it is to be understood that the above parameters are not limiting and those skilled in the art will appreciate that additional parameters may also be employed/manipulated to effectuate the purpose of implanting a highly confined form of the halo 124.

It is to be understood that the order in which the source/drain extension 122 and the halo 124 are formed in not critical, what is important is that the process parameters (e.g., dose and energy) used to form the source/drain extension 122 and the halo 124 be regulated to produce the desired conductivity type and electrical characteristics within each of the source/drain extension 122 and the halo 124. For example, the source/drain extension 122 and the halo 124 may each be formed at a sufficient dose such that the majority concentration of impurities in each is of opposite conductivity type.

In yet other embodiments, the integrated circuit system 100 at this stage of manufacture may also include the source/drain 126, which can be aligned to the second spacer 116. In general, the source/drain 126 may be of the same conductivity type as the dopants used to form the source/drain extension 122 (e.g., n-type impurities for an NMOS device or p-type impurities for a PMOS device).

Generally, the source/drain 126 should be implanted with an energy that is insufficient to reach the first layer 400, thereby preventing implant damage or stress relaxation within the first layer 400. Accordingly, it will be appreciated by those skilled in the art that the implant energy used to form the source/drain 126 may vary with the thickness of the second layer 500. Exemplary energies and doses used to form the source/drain 126 may include an energy between about 1 keV and about 70 keV and a concentration between about 1×10¹⁴ ions/cm²to about 5×10¹⁵ ions/cm².

However, larger or smaller energies and doses may be used depending upon the impurity used and the design specifications of the integrated circuit system 100. Moreover, it is to be understood that the above parameters are not limiting and those skilled in the art will appreciate that additional parameters may also be employed/manipulated to effectuate the purpose of implanting a highly-doped and abrupt form of the source/drain 126.

It will be appreciated by those skilled in the art that an anneal can be performed at this stage of manufacture to activate the dopants depending upon the formation of the source/drain extension 122, the halo 124, or the source/drain 126, and/or the subsequent use of stress memorization transfer layers.

Referring now to FIG. 2, therein is shown the structure of FIG. 1 after the formation of a protective layer 202 and a mask layer 204. The protective layer 202, which may include a low temperature oxide layer, can be formed over the entirety or on selected portions the integrated circuit system 100. It will be appreciated by those skilled in the art that the composition of the protective layer 202 is not critical, what is important is that the protective layer 202 be made from a material that protects the first device 104 from damage during subsequent etching of the substrate 102 and/or be made from a material that helps to block the deposition of a subsequent layer, such as one or more epitaxial layers.

The mask layer 204 may also be formed over the entirety or on selected portions the integrated circuit system 100 and can be patterned to remain over the first device 104. The mask layer 204 shields the protective layer 202 formed over the first device 104 from a subsequent etch step, which removes the protective layer 202 from over the second device 106. By way of example, the subsequent etch step may include an oxide wet etch, if the protective layer 202 includes an oxide material.

In some embodiments, the mask layer 204 can be a positive or negative photoresist material that is patterned to form an opening. In such cases, the mask layer 204 can be deposited and patterned by using materials and techniques well known within the semiconductor processing arts. Generally, the thickness of the mask layer 204 can vary between about 200 nanometers and about 2000 nanometers. However, larger or smaller thicknesses of the mask layer 204 may be appropriate depending on the design specifications of the integrated circuit system 100.

It will be appreciated by those skilled in the art that the thickness range for the mask layer 204 is compatible with sub 65 nanometer technology where the lateral and vertical geometries of the integrated circuit system 100 are greatly reduced. The present inventors have discovered that by maintaining the mask layer 204 thickness below about 2000 nanometers that critical dimension control of sub 65 nanometers devices can be improved.

In other embodiments, the mask layer 204 may include one or more layers, wherein at least one of the layers includes an anti-reflective layer, such as an organic or an inorganic dielectric material that can suppress unintended energy/light reflection from underlying layers. In such cases, the mask layer 204 may include a bottom anti-reflective coating (BARC), for example, that is proximate a top surface of the substrate 102. Generally, the BARC may include one or more thin film layers of different material applied in a selected sequence.

It will be appreciated by those skilled in the art that the application of a BARC can improve the sidewall angle (e.g., create a vertical sidewall) of an opening within the mask layer 204, thereby improving critical dimension control.

In other embodiments, the mask layer 204 may also include a release layer or a primer formed between the top surface of the substrate 102 and the remainder of the mask layer 204, to facilitate removal.

In yet other embodiments, the mask layer 204 may include one or more layers, wherein at least one of the layers includes an anti-reflective layer that can suppress unintended energy/light reflection from underlying layers. In such cases, the mask layer 204 may include a top anti-reflective coating (TARC) that acts as a transparent thin-film interface layer, which uses destructive interference between light rays to eliminate reflectance. Generally, the TARC may include one or more thin film layers of different material applied in a selected sequence.

It will be appreciated by those skilled in the art that the application of the TARC can improve the sidewall angle (e.g., create a vertical sidewall) of an opening within the mask layer 204, thereby improving critical dimension control.

Generally, portions of the mask layer 204 can be removed from over the substrate 102 by employing single step or multi-step etch methods selective to the composition of the mask layer 204. For example, the mask layer 204 can be etched by common wet or dry etch chemistries. However, it is to be understood that the type of etch chemistry used to etch the mask layer 204 is not essential, what is important is that the mask layer 204 is removed from over at least a portion of the second device 106, while remaining portions of the integrated circuit system 100 remain covered by the mask layer 204, thereby protecting these other structures from subsequent processing steps.

In some embodiments, after removal of the protective layer 202 and the mask layer 204 from over the second device 106, the exposed portion of the substrate 102 (e.g., the portions around the second device 106) may undergo a cleaning step to remove surface contaminants, such as particles, mobile ionic contaminants, organics and native oxides, before further processing.

Referring now to FIG. 3, therein is shown the structure of FIG. 2 after further processing. The mask layer 204, of FIG. 3, can be removed from over the first device 104, exposing the protective layer 202 formed over the first device 104. For purposes of illustration, the mask layer 204 may be removed by a plasma or a wet resist strip process.

In one embodiment, a trench 300 can be formed by selectively etching portions of the substrate 102 adjacent the second device 106. Generally, the trench 300 can be aligned to the second spacer 116 and formed to a depth of about 400 angstroms to about 2000 angstroms within the substrate 102. In at least one embodiment, the trench 300 can be formed to a depth of about 500 angstroms to about 800 angstroms. However, larger or smaller depths for the trench 300 may be appropriate depending on the design specifications of the integrated circuit system 100.

Generally, the trench 300 is formed by employing an etch process that is highly selective to the material of the substrate 102. By way of example, if the substrate 102 is made from silicon, the etching process for forming the trench 300 may employ reactive ion etching or other processes that are highly selective to silicon. However, it is to be understood that the etching process employed to form the trench 300 may include any etching process that permits formation of the trench 300 while minimizing any detrimental etching effects upon the protective layer 202 and/or the first device 104.

It will be appreciated by those skilled in the art that the shape of the trench 300 can be strategically engineered to maximize its stress inducing effect upon the channel 112. By way of example, the trench 300 could be enlarged by removing a portion of the substrate 102 underneath the channel 112, thereby permitting the formation of a stress inducing layer in closer proximity to the channel 112 whose thickness and length underneath the channel 112 can be manipulated to increase the stress within the channel 112. For purposes of illustration, the trench 300 may take the form of an “L-shape”, wherein a leg 302 (depicted in dashed outline) of the “L-shaped” form of the trench 300 traverses horizontally underneath a portion of the substrate 102 that is thick enough to contain the channel 112, the source/drain extension 122 (not shown), and the halo 124 (not shown).

Generally, as the open space provided by the leg 302 portion of the trench 300 becomes thicker (e.g., in the vertical direction) and longer (e.g., in the horizontal direction), the amount of stress imparted to the channel 112, by the subsequent formation of a stress inducing layer, increases. As such, the present inventors have discovered that the proximity effect of a subsequently deposited stress-inducing layer can be enhanced by strategically engineering the design/configuration of the trench 300. However, it is to be understood that the trench 300 is not to be limited to a particular configuration or depth. In accordance with the present invention, the trench 300 may include any configuration and/or depth profile that enhances channel stress.

After the etching process, it is to be understood that the integrated circuit system 100 may undergo a cleaning step to remove surface contaminants, such as particles, mobile ionic contaminants, organics and native oxides from within the trench 300. Optionally, the clean step can be in a gaseous form, with mixtures of gases that include HF. The protective layer 202 shields the first device 104 from this clean step.

Referring now to FIG. 4, therein is shown the structure of FIG. 3 after formation of the first layer 400 within the trench 300. Generally, the first layer 400 can be epitaxially grown (e.g., via a selective epitaxial growth process) on or over exposed portions of the substrate 102 within the trench 300, while permitting a stress inducing effect upon the channel 112. The first layer 400 may include any material with a first lattice constant value that exceeds the lattice constant value of the material of the substrate 102.

By way of example, in some embodiments, the exposed portion of the substrate 102 within the trench 300 can be subjected to one or more impurities during the epitaxial growth process such that the first layer 400 may be formed as an n-type doped layer, wherein n-type impurities are used for NMOS devices and p-type impurities are used for PMOS devices.

As an exemplary illustration, the first layer 400 can be made from an epitaxial in-situ n-type doped silicon-germanium (SiGe), wherein the n-type dopant is selected from Group V of the Periodic Table of Elements. In such cases, the first layer 400 may employ a heavily doped phosphorus (P) or arsenic (As) silicon-germanium layer with a dopant concentration of phosphorus/arsenic between about 1×10²⁰ (atoms/cm³) to about 1×10²¹ (atoms/cm³) or a dopant dose of phosphorus/arsenic between about 1×10¹⁴ (atoms/cm²) to about 1×10¹⁶ (atoms/cm²).

In at least one embodiment, a germanium form (e.g., a SiGe layer) of the first layer 400 may include a germanium content ranging from about ten percent (10%) to about one-hundred percent (100%). In other embodiments, a SiGe form of the first layer 400 may include a germanium content ranging from about twenty percent (20%) to about forty percent (40%). It will be appreciated by those skilled in the art that stress imparted by the first layer 400 upon the channel 112 can be strategically modulated by varying the concentration of germanium.

However, it is to be understood that the first layer 400 need not be limited to any particular type of material or concentration. In accordance with the present embodiments, the first layer 400 may include any material and/or composition with a first lattice constant value that exceeds the lattice constant value of the substrate 102. Additionally, the first layer 400 may also include one or more layers with different lattice constant values, so long as the combined lattice constant value of the one or more layers exceeds that of the substrate 102.

Furthermore, it is to be understood that a multitude of deposition parameters, such as reactant flow rates, pressure, temperature, reactant materials, and thickness, can be adjusted to modulate the stress within the first layer 400. Moreover, it will be appreciated by those skilled in the art that the above parameters are not limiting and that additional parameters may also be employed and/or manipulated to effectuate the purpose of forming the first layer 400 with a specified internal stress that will increase the performance of an active device by enhancing the carrier mobility within the channel 112.

Generally, the first layer 400 can be deposited with a thickness ranging from about 400 angstroms to about 2500 angstroms. In at least one embodiment, the first layer 400 can be deposited with a thickness ranging from about 500 angstroms to about 1200 angstroms. It is to be understood that larger or smaller thicknesses of the first layer 400 may be used depending upon the desired stress inducing effects and/or the design specifications of the integrated circuit system 100.

However, the upper limit of the thickness of the first layer 400 should be constrained by the need to avoid implanting the source/drain extension 122 (not shown), the halo 124 (not shown), and/or the source/drain 126 (not shown) within the first layer 400, if not already present. It will be appreciated by those skilled in the art that if the first layer 400 is subjected to halo, extension, source/drain, and/or well implants that the implant damage from such implants can lead to strain/stress relaxation within the first layer 400.

In one embodiment, the first layer 400 can also be formed within the leg 302, of FIG. 3. It will be appreciated by those skilled in the art that the shape or design of the trench 300 and its subsequent filling with the first layer 400 can be strategically manipulated/engineered to vary the amount of stress imparted upon the channel 112 by the first layer 400.

Furthermore, it is to be understood that the selective epitaxy process of the present embodiments provides flexibility for the device designer to optimize performance of the integrated circuit system 100 by controlling epilayer doping, thickness, concentration, and profile, thereby optimizing the stress inducing effect upon the channel 112 by the first layer 400.

Referring now to FIG. 5, therein is shown the structure of FIG. 4 after formation of the second layer 500 within the trench 300. Generally, the second layer 500 can be epitaxially grown (e.g., via a selective epitaxial growth process) on or over exposed portions of the first layer 400 and the substrate 102 within the trench 300. The second layer 500 may include any material with a second lattice constant value that is less than the first lattice constant value exhibited by the first layer 400.

By way of example, in some embodiments, the second layer 500 can be subjected to one or more impurities during the growth/deposition process such that the second layer 500 may be formed as an n-type doped layer, wherein n-type impurities are used for NMOS devices and p-type impurities are used for PMOS devices.

In other embodiments, the second layer 500 may not be doped during the epitaxial growth process, but can be subsequently doped by an implantation or diffusion of impurities.

As an exemplary illustration, the second layer 500 can be made from an epitaxial in-situ n-type doped silicon or an epitaxial in-situ n-type doped silicon carbide (SiC), wherein the n-type dopant is selected from Group V of the Periodic Table of Elements. In such cases, the second layer 500 may employ a heavily doped phosphorus (P) or arsenic (As) silicon or silicon-carbide layer with a dopant concentration of phosphorus/arsenic between about 1×10²⁰ (atoms/cm³) to about 1×10²¹ (atoms/cm³) or a dopant dose of phosphorus/arsenic between about 1×10¹⁴ (atoms/cm²) to about 1×10¹⁶ (atoms/cm²).

In at least one embodiment, a SiC form of the second layer 500 may include a carbon content ranging from about one percent (1%) to about three percent (3%).

However, it is to be understood that the second layer 500 need not be limited to any particular type of material or concentration. In accordance with the present embodiments, the second layer 500 may include any material and/or composition with a second lattice constant value that is less than the first lattice constant value of the first layer 400. Additionally, the second layer 500 may also include one or more layers with different lattice constant values, so long as the combined lattice constant value of the one or more layers is less than that of the first layer 400.

Furthermore, it is to be understood that a multitude of deposition parameters, such as reactant flow rates, pressure, temperature, reactant materials, and thickness, can be adjusted to modulate the stress within the second layer 500. Moreover, it will be appreciated by those skilled in the art that the above parameters are not limiting and that additional parameters may also be employed and/or manipulated to effectuate the purpose of forming the second layer 500 with a specified internal stress that will increase the performance of an active device by enhancing the carrier mobility within the channel 112.

Generally, the second layer 500 can be deposited with a thickness ranging from about 400 angstroms to about 2500 angstroms. In at least one embodiment, the second layer 500 can be deposited with a thickness ranging from about 400 angstroms to about 1200 angstroms. It is to be understood that larger or smaller thicknesses of the second layer 500 may be used depending upon the desired stress inducing effects and/or the design specifications of the integrated circuit system 100. It will be appreciated by those skilled in the art that the second layer 500 may extend beyond the plane established by the top surface of the substrate 102.

However, the lower limit of the thickness of the second layer 500 should be constrained by the need to implant the source/drain extension 122 (not shown), the halo 124 (not shown), and/or the source/drain 126 (not shown) only within the second layer 500, if not already present. In at least one embodiment, the implantation parameters for each of the source/drain extension 122, the halo 124, and/or the source/drain 126 can be optimized to ensure that no dopants are implanted within the first layer 400 (e.g., by controlling the energy and angle of the implant). It will be appreciated by those skilled in the art that if the first layer 400 is subjected to halo, extension, source/drain, and/or well implants that the implant damage from such implants can lead to strain/stress relaxation within the first layer 400 and a corresponding reduction in stress imparted upon the channel 112.

In one embodiment, the first layer 400 and the second layer 500 can be formed within the leg 302, of FIG. 3. It will be appreciated by those skilled in the art that the shape or design of the trench 300 and its subsequent filling with the first layer 400 and the second layer 500 can be strategically manipulated to vary the amount of stress imparted upon the channel 112 by the first layer 400 and the second layer 500.

Furthermore, it is to be understood that the selective epitaxy process of the present embodiments provides flexibility for the device designer to optimize performance of the integrated circuit system 100 by controlling epilayer doping, thickness, concentration, and profile, thereby optimizing the stress inducing effect upon the channel 112 by the first layer 400 and/or the second layer 500.

Moreover, it will be appreciated by those skilled in the art that the overall thickness of the first layer 400 and the second layer 500 can depend upon the extent to which subsequent processing steps will recess the second layer 500 and/or the first layer 400. For example, if the second layer 500 is too thin, then subsequent processing steps, such as a spacer etch, may recess the second layer 500 and/or the first layer 400, thereby affecting the formation of shallow junctions formed within the second layer 500.

Referring now to FIG. 6, therein is shown the structure of FIG. 5 after further processing. Subsequent to forming the second layer 500, the protective layer 202, of FIG. 5, can be removed by etchants and processes well known within the art. Additionally, subsequent to forming the second layer 500, if not already formed, the source/drain extension 122, the halo 124, and/or the source/drain 126 can be formed within the second layer 500. Notably, the methodology disclosed by the present inventors permits the formation of the first layer 400 and the second layer 500 before or after each of the source/drain extension 122, the halo 124, and/or the source/drain 126, thereby easing process latitude and integration requirements.

Additionally, it is to be understood that the implant energy used to form the source/drain extension 122, the halo 124, and/or the source/drain 126 may possess sufficient energy to amorphize at least a portion of the substrate 102 and/or at least a portion of the gate 108. An implant with sufficient energy to amorphize at least a portion of the substrate 102 and/or at least a portion of the gate 108 allows a subsequent anneal step to transfer/memorize a stress to the gate 108 and to the substrate 102 during recrystallization from a stress memorization transfer layer, thereby promoting stress within the channel 112 and improving the performance of the integrated circuit system 100.

Generally, the integrated circuit system 100 may also include an electrical contact 600, such as a low resistance silicide or salicide electrical contact, formed over the gate 108 and the source/drain 126. In some embodiments, the electrical contact 600 may include any conducting compound that forms an electrical interface between itself and another material that is thermally stable and provides uniform electrical properties with low resistance. In other embodiments, the electrical contact 600 may include refractory metal materials such as, tantalum (Ta), cobalt (Co), titanium (Ti), tungsten (W), platinum (Pt), or molybdenum (Mo). In yet other embodiments, the electrical contact 600 formed over the source/drain 126 can be aligned to the second spacer 116 via a salicide process.

It will be appreciated by those skilled in the art that the electrical contact 600 can affect the mobility of carriers (e.g., due to stresses imparted by the electrical contact 600) within the channel 112 of either the first device 104 or the second device 106. For example, in cases where the first device 104 includes a PMOS device, if the electrical contact 600 is placed too close to the channel 112 of the first device 104, the electrical contact 600 can detrimentally affect the mobility of carriers within the channel 112. As such, it is to be understood that the thickness of the first spacer 114 and the second spacer 116 can be modulated (e.g., by increasing the thickness) to reduce or negate the detrimental effect that the electrical contact 600 can have on carrier mobility within the channel 112 of the first device 104.

Alternatively, the thickness of the first spacer 114 and the second spacer 116 can also be modulated (e.g., by decreasing the thickness) to enhance the effect that the electrical contact 600 can have on carrier mobility within the channel 112 of the second device 106. Accordingly, the thickness of the first spacer 114 and the second spacer 116 can be modulated to enhance or reduce the effects that the electrical contact 600 could have on the stress level within the first device 104 and the second device 106.

Furthermore, it is to be understood that the integrated circuit system 100 may undergo a cleaning step to remove surface contaminants, such as particles, mobile ionic contaminants, organics and native oxides, before formation of the electrical contact 600.

Additionally, it will be appreciated by those skilled in the art that other stress engineered layers can be deposited over the integrated circuit system 100 for purposes of exerting additional stresses upon each of the channel 112. In such cases, the additional stress engineered layers can be strategically designed and deposited to exert compressive and/or tensile stresses, depending upon the type of device (e.g., tensile for NMOS and compressive for PMOS).

For example, the stress engineered layers may include a first dielectric layer 602 and a second dielectric layer 604. The first dielectric layer 602 can be deposited over the first device 104 and may be engineered to promote a compressive strain within the channel 112 of the first device. By way of example, the first dielectric layer 602 may include a silicon nitride layer deposited by a plasma enhanced chemical vapor deposition process. In such cases, it is to be understood that a multitude of deposition parameters, such as reactant flow rates, pressure, temperature, RF power and frequency, reactant materials, and thickness, can be adjusted to modulate the compressive stress within the first dielectric layer 602. Moreover, it will be appreciated by those skilled in the art that the above parameters are not limiting and that additional parameters may also be employed and/or manipulated to effectuate the purpose of forming the first dielectric layer 602 with a specified internal stress that will increase the performance of an active device by enhancing the carrier mobility within the channel 112. In other embodiments, the first dielectric layer 602 may also include a stress memorization layer that transfers its stress to the first device 104 upon annealing.

In some embodiments, the proximity of the first dielectric layer 602 to the channel 112 of the first device 104 can be facilitated by the formation of a shallow recess adjacent the channel 112 by processes well known in the art. By way of example, the shallow recess can allow the placement of the first dielectric layer 602 closer to the channel 112, thereby promoting current enhancing stress within the channel 112 of the first device 104.

The second dielectric layer 604 can deposited over the second device 106 and may be engineered to promote a tensile strain within the channel 112 of the second device 106. By way of example, the second dielectric layer 604 may include a silicon nitride layer deposited by a plasma enhanced chemical vapor deposition process. In such cases, it is to be understood that a multitude of deposition parameters, such as reactant flow rates, pressure, temperature, RF power and frequency, reactant materials, and thickness, can be adjusted to modulate the tensile stress within the second dielectric layer 604. Moreover, it will be appreciated by those skilled in the art that the above parameters are not limiting and that additional parameters may also be employed and/or manipulated to effectuate the purpose of forming the second dielectric layer 604 with a specified internal stress that will increase the performance of an active device by enhancing the carrier mobility within the channel 112. In other embodiments, the second dielectric layer 604 may also include a stress memorization layer that transfers its stress to the second device 106 upon annealing.

In any case, the second dielectric layer 604 can augment and/or enhance the tensile strain effects of the first layer 400 and the second layer 500 upon the channel 112 of the second device 106.

It is to be understood that the specified internal stress within either of the first dielectric layer 602 or the second dielectric layer 604 may be selected so as to efficiently produce a desired stress level within each of the channel 112 of the first device 104 and the second device 106 in accordance with design and performance requirements of the integrated circuit system 100. By stress engineering the first dielectric layer 602 and/or the second dielectric layer 604 with an appropriate stress, carrier mobility within the channel 112 of the first device 104 and the second device 106 can be enhanced, thereby improving the performance of the integrated circuit system 100.

Moreover, it will be appreciated by those skilled in the art that the size and/or width of the first spacer 114 and the second spacer 116 can affect the performance of the first device 104 and the second device 106 due to their ability to offset the first dielectric layer 602 and the second dielectric layer 604 from each of the channel 112. Accordingly, the present embodiments permit the design engineer to configure the size and/or width of the first spacer 114 and the second spacer 116 to optimize the compressive or tensile stress of a subsequently deposited stressed inducing etch stop layer or stress inducing stress memorization layer upon each of the channel 112.

As such, it has been discovered by the present inventors that the integrated circuit system 100 of the present invention facilitates the incorporation of both NMOS and PMOS channel stress, thereby improving the current carrying capability of the integrated circuit system 100.

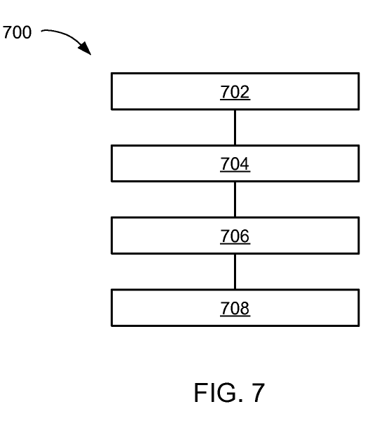

Referring now to FIG. 7, therein is shown a flow chart of an integrated circuit system 700 for the integrated circuit system 100, in accordance with an embodiment of the present invention. The integrated circuit system 700 includes providing a substrate including an active device in a block 702; forming a trench within the substrate adjacent the active device in a block 704; forming a first layer with a first lattice constant within the trench in a block 706; and forming a second layer with a second lattice constant over the first layer, the second lattice constant differing from the first lattice constant in a block 708.

It has been discovered that the present invention thus has numerous aspects. One such aspect is that the present invention helps to increase the stress within a channel of an NMOS device by forming first and second layers with different lattice constants within a trench adjacent the channel region of the NMOS device.

Another aspect of the present invention is that the stress within a first layer can be maintained by preventing the implantation of dopants during formation of a source/drain extension, a halo region, a source/drain region, and/or a well region.

Another aspect of the present invention is that the stress within an NMOS channel can be modulated by altering the shape of a trench region formed adjacent the NMOS device.

Another aspect of the present invention is that the stress within adjacent active devices can be modulated by employing proven strain engineering technologies such as stress memorization transfer layers and/or compressive/tensile liners.

Another aspect of the present invention is that it permits the use of a mature technology such as SiGe/Si epitaxy within NMOS strain engineering.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit system of the present invention furnishes important and heretofore unknown and unavailable solutions, capabilities, and functional aspects for improving carrier mobility with a controlled application of stress to the channel of an active device. The resulting processes and configurations are straightforward, cost-effective, uncomplicated, highly versatile and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. A method for manufacturing an integrated circuit system comprising:
providing a substrate including an active device;
forming a trench within the substrate adjacent the active device;
forming a first layer with a first lattice constant within the trench; and
forming a second layer with a second lattice constant over the first layer, the second lattice constant differing from the first lattice constant.

2. The method as claimed in claim 1 wherein:
providing the substrate including the active device includes providing an NMOS device.

3. The method as claimed in claim 1 wherein:
forming the first layer with the first lattice constant includes forming the first layer with a first lattice constant value that exceeds a lattice constant value of the substrate.

4. The method as claimed in claim 1 wherein:
forming the second layer with the second lattice constant includes forming the second layer with a second lattice constant value that is less than a first lattice constant value.

5. The method as claimed in claim 1 wherein:
forming the first layer and the second layer induces stress upon a channel of the active device.

6. A method for manufacturing an integrated circuit system comprising:
providing a substrate including a CMOS structure with a first device and a second device;
forming a trench within the substrate adjacent the second device;
forming a first layer with a first lattice constant within the trench; and
forming a second layer with a second lattice constant within the trench, the second lattice constant differing from the first lattice constant.

7. The method as claimed in claim 6 wherein:
providing the first device includes providing a PMOS device and providing the second device includes providing an NMOS device.

8. The method as claimed in claim 6 wherein:
forming the first layer includes forming a layer with a germanium concentration between about 10% and about 100%.

9. The method as claimed in claim 6 wherein:
forming the second layer includes forming a layer with a carbon concentration between about 1% and about 3%.

10. The method as claimed in claim 6 further comprising:
forming a first dielectric layer over the first device and a second dielectric layer over the second device.

11. An integrated circuit system comprising:
a substrate including an active device; and
a trench within the substrate adjacent the active device, the trench including a first layer with a first lattice constant and a second layer with a second lattice constant, the second lattice constant differing from the first lattice constant.

12. The system as claimed in claim 11 wherein:
the active device includes providing an NMOS device.

13. The system as claimed in claim 11 wherein:
the first layer with the first lattice constant includes the first lattice constant value exceeding a lattice constant value of the substrate.

14. The system as claimed in claim 11 wherein:
the second layer with the second lattice constant includes the second lattice constant value being less than the first lattice constant value.

15. The system as claimed in claim 11 wherein:
the first layer and the second layer induce stress upon a channel of the active device.

16. The system as claimed in claim 11 wherein:
the first layer includes a silicon-germanium material.

17. The system as claimed in claim 11 wherein:
the second layer includes silicon or a silicon-carbide material.

18. The system as claimed in claim 11 wherein:
the first layer includes a layer with a germanium concentration between about 10% and about 100%.

19. The system as claimed in claim 11 wherein:
the second layer includes a layer with a carbon concentration between about 1% and about 3%.

20. The system as claimed in claim 11 further comprising:
a first dielectric layer over the first device and a second dielectric layer over the second device.
